(19) United States
(12) Patent Application Publication
(10) Pub. No.: US 2014/0332050 A1
(43) Pub. Date: Nov. 13, 2014

(54) SOLAR CELL STRING, METHOD AND DEVICE FOR CONNECTING SOLAR CELLS TO A SOLAR CELL STRING

(71) Applicant: Komax Holding AG, Dierikon (CH)

(72) Inventors: Stefan Kaufmann, Aarau (CH); Adolf Hofer, Lufingen (CH)

(21) Appl. No.: 14/258,090

(22) Filed: Apr. 22, 2014

(30) Foreign Application Priority Data
May 8, 2013 (EP) 13167080.4

(51) Int. Cl. H01L 31/05; H01L 31/18

(52) U.S. Cl. CPC H01L 31/0508; H01L 31/18
USPC 136/244; 438/80; 29/747

(57) ABSTRACT

A solar cell string having a plurality of solar cells disposed in a row includes contact elements for electrically connecting the solar cells. The contact elements have cup-shaped indentations, created through deep-drawing or stamping, that establish contact with the solar cells through holes in insulating strips applied to the solar cells.

### FIELD

The invention relates to a solar cell string, a method, and a device for connecting solar cells in a solar cell string. The invention is suitable in particular for connecting so-called back-surface solar cells, which are distinguished in that the contact zones, i.e. the p-doped and n-doped regions, are located on the same side of the solar cell.

### BACKGROUND

FIG. 1 shows a generic comparable solar cell string 1 according to the prior art. Details regarding the construction and design of the connection assembly of the known solar cell strings can be derived from FIG. 2, which concerns a string made of back-surface solar cells. For the electrical connection of the solar cells 2, 2′, a copper strip 3, 3′ created by means of a bending shaping process is used. An insulating strip 4, 4′ extending in the x-axis is disposed on the back surface of the solar cell, having holes 5, wherein the holes expose n-doped contact zones 10. The zone 10 is familiar to the person skilled in the art by the term “n-pad”. The contact element 3 is designed as a bent component, and has bent edges, which are indicated by the parallel lines 11, running transversally to the x-axis to form a bridging section 8. The known contact elements are comparably narrow; the maximal width of the contact element 3 is limited by the diameter d of the hole. Narrow contact elements of this type lead to an undesired power loss due to the relatively high ohmic resistance.

### SUMMARY

It is therefore the objective of the invention to create a solar cell string of the type specified above, which can be operated more energy efficiently. In particular, the connections of the solar cells should be distinguished by low ohmic losses. The efficiency of a solar module comprising one or more solar strings of this type should be optimized.

This objective is attained by a solar cell string having numerous solar cells disposed in a row along a longitudinal direction and preferably connected by means of contact elements formed by a metal strip (e.g. of copper). A contact element of this type connects, in each case, two adjacent solar cells to one another. At least for the contact regions having the n-poles, or the n-doped zone, respectively, the solar cells are provided with the insulating material, which, in each case, exhibits a hole, by means of which the contact element is in contact with the solar cells. The insulating material can be a strip extending in the longitudinal direction. By way of example, a preferably one-sided adhesive insulating strip can be used for the insulation, consisting of a plastic material that does not conduct, or only slightly conducts, electricity. An adhesive strip of this type can be readily attached to the solar cells by being pressed against the surface of the solar cell. Of course, other means of attaching the insulation strips to the solar cells are also conceivable. Solder resist, for example, may also be considered for the insulating material, which is applied to the solar cells by means of screen printing. Instead of one or more insulating strips, for example, the solar cells could accordingly be provided with strips of solder resist having basically the same dimensions. Insulating material can, however, also be applied to the solar cells in another coating process or by other means. If the solar cells have numerous rows of n-poles, then the solar cells can be provided, preferably, with a corresponding number of insulating strips applied thereto. Because, in order to create the contact between the contact element and the solar cells, the contact received in the at least one hole has an indentation, numerous advantages are realized. Because of the contact element provided with indentations, wider contact elements can be used, as a result of which the transmission capacity can be significantly increased due to reduced ohmic losses. Thus, the efficiency of a solar module made of solar cell strings of this type can be improved. Depending on the design of the indentation, it is also possible to obtain an improved contact between the contact element and the solar cells.

If the contact element is, for example, a metal strip, it may be advantageous if the indentation is a cup-like indentation, preferably created by means of a deep-drawing or stamping process, in the metal strip. Cup-shaped indentations of this type can be easily produced.

In order to create an advantageous contact surface on the surface of the solar cells, the indentations can exhibit a flat bottom.

The hole, and/or the indentation allocated to the hole can be circular when seen from above. By way of example, a basically complementary circular indentation is particularly preferably allocated to a hole in the form of a circular hole. Of course, other hole shapes and indentation shapes are also conceivable. The holes could, for example, be oval. Polygonal hole shapes and indentation shapes can also be considered. It is particularly advantageous if the holes and indentations have the same shape, wherein, normally, the indentation should be smaller than the hole. As long as the indentation fits into the hole, different shapes could also be considered.

If the contact element, when seen from above, overlaps the at least one hole, i.e. if the respective contact element is wider than the hole when seen from above, then a particularly energy efficient solar cell string is obtained.

The assembly can be further optimized if the contact element is at least 25%, preferably at least 50%, and particularly preferably approx. 100%, wider than the diameter of the at least one hole. For certain applications, the solar cells of the solar cell strings can be furnished with even wider contact elements.

For mechanically stable connections, the respective contact elements can exhibit at least one flat section in the region of an indentation, which lies on the insulating material. The indentation is elevated with respect to the specified flat section. The depth of the indentation would then correspond to the thickness of the insulating material. Theoretically, it would also be possible to provide deeper indentations (the depth of the indentation is greater than the thickness of the insulating material), resulting in a spacing, or gap, respectively, between the solar cell surface and the flat section of the insulating material.

The respective contact element can exhibit at least two flat sections, which are connected by an exposed bridging section at a spacing to the solar cells. The contact element has two corresponding indentations accordingly, preferably elevated in relation to the flat sections.

Another aspect of the invention relates to a method for connecting solar cells, and in particular, for connecting back-surface solar cells in a solar cell string, in particular, the solar cell string described above. The method comprises the following steps: a prefabricated insulating material in the form of an insulating strip, provided at least in sections with holes, is applied to the solar cells. By way of example, insulating strips provided with holes are used for this. These insulating strips are placed on the solar cells such that the holes leave the n-contact zones exposed. In a next step, the contact elements are produced, in that indentations are formed, by means of a deep-drawing or stamping process, in metal strips. Subsequently, the contact elements created in this manner can be applied to the solar cells, wherein the indentations are placed in the respective holes during the application process.

Another aspect of the invention relates to device for creating an electrical connection between the solar cells by means of contact elements, preferably for executing the method described above. The device comprises an application unit for applying insulating material provided with holes to the solar cells, and a stamping or deep-drawing unit having at least one die stamp for creating indentations aligned with the holes in contact elements formed from metal strips.

A respective contact element can have numerous indentations. In order for the indentations to be able to be created in a single step, it can be advantageous if the stamping or deep-drawing unit exhibits numerous die stamps. It is of course also conceivable for the indentations to be created using only one die stamp for each contact element.

The die stamp, or die stamps, can be designed as knob-like projections, by means of which, in a particularly simple manner, cup-shaped indentations can be formed in a metal strip.

### DESCRIPTION OF THE DRAWINGS

Further individual features and advantages of the invention can be derived from the following description of an embodiment example and from the drawings. Shown are:

FIG. 1 is a top plan view of a solar cell string according to the prior art.

FIG. 2 is an enlarged fragmentary perspective illustration of a contact between solar cells and contact elements of the solar cell string shown in FIG. 1.

FIG. 3 is an enlarged fragmentary perspective illustration of a contact between solar cells and contact elements of a solar cell string according to the invention.

FIG. 4 is a flow diagram of a method for connecting solar cells to a solar cell string according to the invention.

FIG. 5 is a block diagram of a device for connecting solar cells to a solar cell string according to the invention.

### DETAILED DESCRIPTION

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

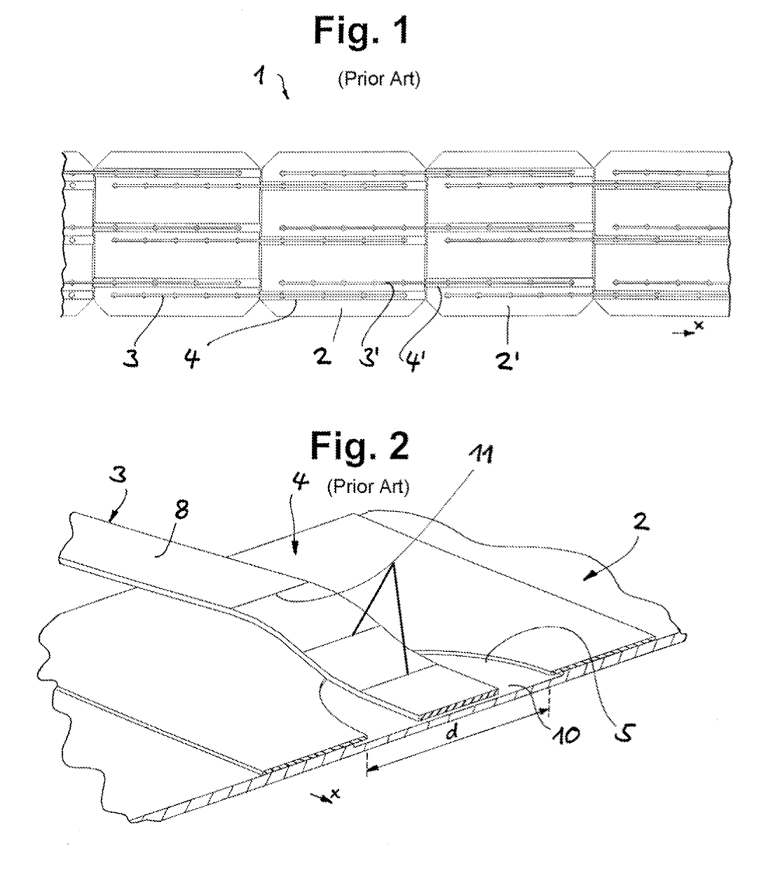

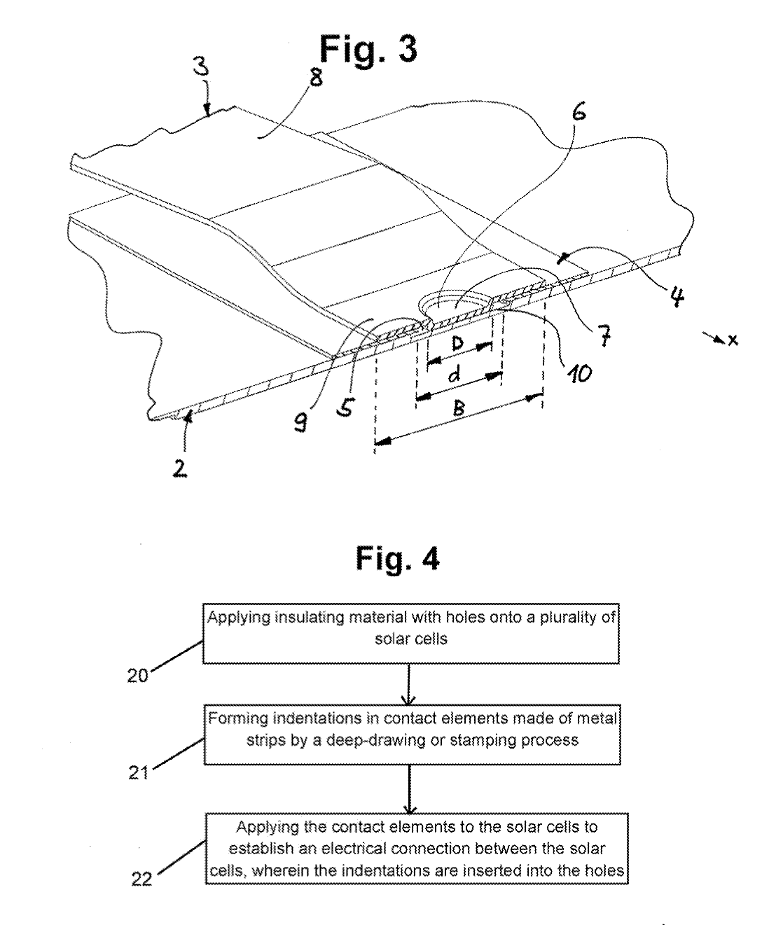

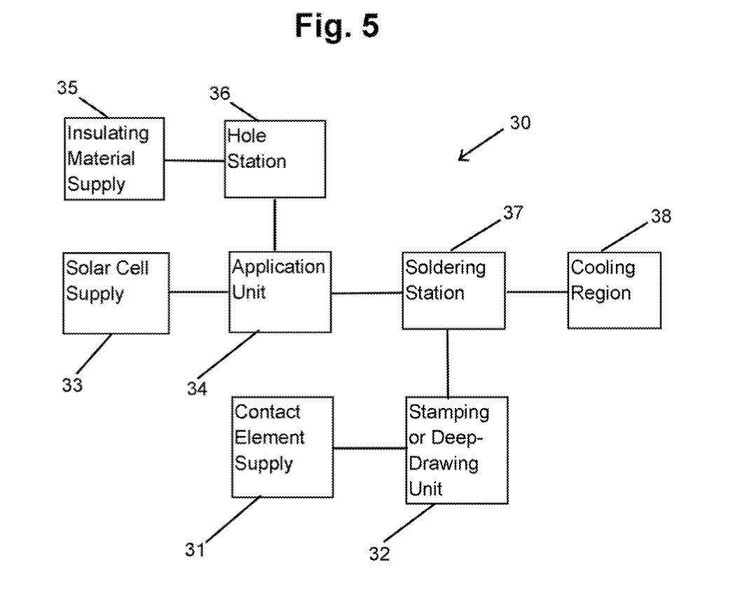

FIG. 3 shows a contact between a solar cell 2 and a contact element 3 in a solar cell string according to the invention. Aside from the specially designed contact elements described in detail below, the solar cell string is basically constructed in the same manner as that in FIG. 1. Back-surface solar cells 2 are electrically connected by means of contact elements 3 of this type. The contact element 3, produced from a metal strip, connects, in each case, one or more n-doped regions (− poles) of a solar cell to one or more p-doped regions (+ poles). As shown in FIG. 3, the insulating strip 4, known per se, extending in the longitudinal direction x, is disposed on the solar cell 2 in the region of the n-pole (cf. FIG. 2). The insulating strip 4 substantially consists of a material that is not electrically conductive, or is only slightly electrically conductive, for example, made of a flexible plastic material. The insulating material can be designed as an adhesive strip, such that it can be particularly easily, and in a single step (by means of pressure), applied to the solar cells. Insulating strips of this type are inexpensive and are available in different widths, thicknesses, and compositions, and can be adapted to the respective purpose in an optimal manner. The insulating strip 4 has at least one hole 5, by means of which a contact is created between the contact element 3 and the solar cell 2 at the n-doped contact zone. The hole 5 enables the contact zone (“n-pad”) indicated by the numeral 10 to be left exposed, by means of which a contact to the solar cell 2 can be established through the contact element 3.

In order to establish the contact to the respective n-doped contact zone 10, the contact element 3 has a cup-shaped indentation 6, which can be easily created by means of a deep-drawing or stamping process, using a die stamp for example. The contact element 3 is made of a metal strip having a width B, which is shaped by means of cutting and a folding process, or some other shaping process. As a result of this shaping, mechanical tension relief structures are created. These mechanical tension relief structures can prevent, or at least reduce, undesired, thermally influenced expansions or warpings of the solar cells occurring during the creation of the of the contact as a result of, e.g. soldering or welding. Copper strips, for example, can be used for the contact elements, which have been plated with tin (solder coated) or with silver. Other materials, however, are also conceivable (such as aluminum). The deep-drawing or stamping for creating the indentations can occur prior to, during, or after the creation of the tension relief structures. As a rule, each insulating strip, allocated in each case to one solar cell, has numerous holes, wherein each hole is allocated to one n-doped contact zone. Accordingly, the associated contact element also has numerous indentations 6, corresponding to the number of holes. Analogous to the overall assembly shown in FIG. 1, the solar cell string can have, on each solar cell, numerous contact elements running parallel to one another. By way of example, the solar cell string can have three contact rows running in the longitudinal direction, having contact elements disposed in pairs. Each of the three pairs of contact elements comprises two contact elements thereby, which are oriented in alternating directions, corresponding to the alternating application of the insulating material (cf. FIG. 1).

The indentation 6 has a flat bottom 7, for creating an electrically advantageous contact surface. Both the hole 5, as well as the indentation 6 allocated to the hole, are circular when seen from above. The cup diameter D is somewhat smaller than the hole diameter d, such that, on one hand, a simple insertion of the indentation in the hole, and a secure electrical connection (e.g. by means of soldering, gluing, and/or welding) is ensured. In contrast to the known solution, shown in FIG. 2, the contact element 3 shown here is wider than the hole 5 in the insulating material 4, by means of which the transmission capacity of the solar cell connections can be significantly improved. In other words, the contact element 3 overlaps the hole 5. The diameter of the hole 5 is indicated by the letter d. The width of the contact element can thus be decoupled from the width of the n-pad due to the deep-drawn or stamped contact sections, by means of which the design possibilities and freedom regarding the configuration and dimensions of the contact elements are expanded. In the present example, the contact elements 3 are basically twice as wide as the diameter d for the holes 5. Very good results, however, can also be obtained if the contact elements are at least 25% wider than the diameter of the holes 5. By this means, it is possible, for example, to establish contact, with a contact element 3 having a width of four mm or five mm, resulting in a high degree of modularity, to a two mm wide n-pad 10, resulting in a high degree of cell efficiency. As a result, both the cell efficiency as well as the modularity are maximized. The contact element 3 has a surface of a flat section 9 in the region of each indentation 6, which lies on the insulating material 4. The depth of the indentation thus corresponds to the thickness of the strip-shaped insulating material 4. The flat sections 9 are connected by means of exposed bridging sections 8, spaced apart from the solar cells.

FIG. 4 is a flow diagram of a method for connecting a plurality of back-surface solar cells to form a solar cell string, comprising the steps of: applying insulating material with holes onto the solar cells 20; forming indentations in contact elements made of metal strips by a deep-drawing or stamping process 21; and applying the contact elements to the solar cells to establish an electrical connection between the solar cells, wherein the indentations are inserted into the holes 22. The step 20 can include forming the indentations 6 with a cup-shape having a flat bottom 7 creating a contact surface as shown in FIG. 3.

In terms of the device 30 for connecting a plurality of back-surface solar cells to form a solar cell string, the invention is distinguished in that it has a contact element supply 31 providing the contact elements 3 to a stamping or deep-drawing unit 32, with which indentations 6 can be incorporated in the contact elements made of metal strips. The device 30 can also comprise a solar cell supply 33 providing individual solar cells 2 to an application unit 34, for applying the insulating material 4, preferably in the form of an insulating strip from an insulating material supply 35, on the solar cells. The insulating strip 4 can already be provided with the holes 5, which are created in a prefabrication procedure. It is also conceivable that the device 30 specified above also comprises a means for creating the holes (e.g. a hole station 36) in the insulating strip. The solar cells 2 furnished with the contact elements 3 can pass through a soldering station 37 having a pre-heating zone, in which the electrical contacts are created to form the solar cell string. A cooling region 38 for the solar cell string can be incorporated downstream of the soldering station 37.

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. A solar cell string having a plurality of solar cells positioned in a row along a longitudinal direction, and a plurality of contact elements for electrically connecting the solar cells, wherein each contact element is a metal strip and connects two adjacent ones of the solar cells to one another, wherein at least one of the adjacent solar cells includes an insulating material having at least one hole formed therein receiving the contact element to establish an electrical contact with the at least one adjacent solar cell, comprising: the contact element having an indentation formed therein and received in the at least one hole.

2. The solar cell string according to claim 1 wherein the solar cells are back-surface solar cells.

3. The solar cell string according to claim 1 wherein the indentation is a cup-shaped.

4. The solar cell string according to claim 1 wherein the indentation has a flat bottom creating a contact surface.

5. The solar cell string according to claim wherein at least one of the at least one hole and the indentation are circular or oval in shape in plan view.

6. The solar cell string according to claim 1 wherein the contact element overlaps the at least one hole on all sides in plan view.

7. The solar cell string according to claim 6 wherein the contact element is wider than a diameter of the at least one hole by an amount in a range of approximately 25% to approximately 100%.

8. The solar cell string according to claim 1 wherein the contact element has at least one flat section including the indentation, a surface of the at least one flat section lying against the insulating material.

9. The solar cell string according to claim 8 wherein the contact element has another flat section and the flat sections are connected by an exposed bridging section.

10. The solar cell string according to claim 1 wherein the indentation has a depth equal to or greater than a thickness of the insulating material.

11. A method for connecting a plurality of back-surface solar cells to form a solar cell string, comprising the steps of:
applying insulating material with holes onto the solar cells;
forming indentations in contact elements made of metal strips by a deep-drawing or stamping process; and
applying the contact elements to the solar cells to establish an electrical connection between the solar cells, wherein the indentations are inserted into the holes.

12. The method according to claim 11 including forming the indentations with a cup-shape having a flat bottom creating a contact surface.

13. A device for electrically connecting a plurality of back-surface solar cells with contact elements to form a solar cell string, comprising:
an application unit for applying insulating material provided with holes onto the solar cells; and
a stamping or deep-drawing unit for creating indentations in contact elements formed from metal strips, wherein the indentations fit into the holes for electrically connecting the solar cells in the solar cell string.

14. The device according to claim 13 wherein the stamping or deep-drawing unit forms at least two of the indentations simultaneously in one of the contact elements.

15. The device according to claim 13 wherein the stamping or deep-drawing unit forms the indentations as cup-shaped.

16. The device according to claim 13 including a soldering station for electrically connecting the indentations to the solar cells through the holes in the insulating material.
